(19) United States
(12) Patent Application Publication
(10) Pub. No.: US 2015/0069624 A1
(43) Pub. Date: Mar. 12, 2015

(54) RECESSED SEMICONDUCTOR DIE STACK

(71) Applicant: Freescale Semiconductor, Inc., Austin, TX (US)

(72) Inventors: Tim V. Pham, Austin, TX (US); Fonzell D. Martin, Plfugerville, TX (US); Derek S. Swanson, Austin, TX (US)

(73) Assignee: Freescale Semiconductor, Inc., Austin, TX (US)

(21) Appl. No.: 14/024,742

(22) Filed: Sep. 12, 2013

(51) Int. Cl. H01L 23/48; H01L 25/11

(52) U.S. Cl. CPC H01L 23/481; H01L 25/117
USPC 257/774; 438/109

(57) ABSTRACT

Recessed semiconductor die stacks. In some embodiments, a semiconductor device includes a first die including an active side and a back side, the back side including a non-recessed portion thicker than a recessed portion, the recessed portion including one or more through-die vias on a recessed surface; and a second die located in the recessed portion, the second die including an active side facing the recessed surface of the first die and coupled thereto through the one or more through-die vias. In another embodiment, a method includes creating a recess on a first die having a first thickness, the recess having a depth smaller than the first thickness; coupling a second die having a second thickness greater than the depth to the recess; and reducing the thickness of the second die by an amount equal to or greater than a difference between the second thickness and the depth.

### FIELD

This disclosure relates generally to semiconductors, and more specifically, to recessed semiconductor die stacks.

### BACKGROUND

In packaging integrated circuits, it may be desirable to provide a package that allows for multiple semiconductor die within the package. There are several advantages to including multiple die within one package. For example, both packaging costs and the amount of space required on a printed circuit board can be reduced.

One way to accommodate multiple die within a package is to stack one die on top of another die. However, stacking multiple die results in an increased thickness of the resulting package. To address these, and other problems, the inventors hereof have developed fabrication and assembly processes that enable the stacking of multiple die while reducing package volume per die.

### BRIEF DESCRIPTION OF THE DRAWINGS

The present invention(s) is/are illustrated by way of example and is/are not limited by the accompanying figures, in which like references indicate similar elements. Elements in the figures are illustrated for simplicity and clarity and have not necessarily been drawn to scale.

FIG. 1 is a cross-sectional view of an example of a packaged electronic device including a recessed semiconductor die stack, according to some embodiments.

FIGS. 2-5 are diagrams illustrating examples of semiconductor processing operations that may be used to create a recessed semiconductor die stack, according to some embodiments.

FIG. 6 is a cross-sectional view of an example of a recessed semiconductor die stack having three semiconductor dies, according to some embodiments.

FIG. 7 is a flowchart of an example of a method for creating a recessed semiconductor die stack, according to some embodiments.

FIG. 8 is a diagram of an example of an electronic device having one or more electronic microelectronic device packages, according to some embodiments.

### DETAILED DESCRIPTION

Disclosed herein are systems and methods for recessed semiconductor die stacks. In various embodiments, a die stack may include two or more semiconductor dies. Each die may have an active side or surface—that is, a side or surface of the die upon which electronic, microelectronic, and/or electro-mechanical components have been fabricated—and a back or passive side. In some implementations, the back side of a first semiconductor die may have a non-recessed portion that is thicker than a recessed portion, and the recessed portion may include a plurality of through-silicon vias (TSVs), also referred to in this case as through-die vias. A second semiconductor die may be disposed within the recessed portion of the first semiconductor die, and it may be coupled to the first semiconductor die through the TSVs, thus forming a die stack.

In some embodiments, to create a recessed die stack, a semiconductor wafer of any suitable thickness (e.g., 750 μm, etc.) may be received. The wafer may include a plurality of dies manufactured thereon. In some cases, for example, each given die (referred to herein as a “first die,” “core die,” or “first/core semiconductor die”) on the wafer may have a thickness of approximately 100 μm. In some implementations, the first semiconductor die may include a processor or the like.

While still a part of the wafer, the back side of the first semiconductor die may be selectively etched or grinded to create a recessed portion. The recessed portion may have a thickness smaller than the original thickness of the die. Then, a second, already-singulated semiconductor die (also referred to as a “secondary die”), may be inserted in the recessed portion of the first semiconductor die and coupled to its TSVs. For example, in some implementations, the secondary die may include a memory or the like.

Thereafter, the resulting die stack may be backgrinded, planarized, or otherwise thinned so as to align the back sides of the core die and secondary die into a single plane, thus creating a stack of uniform thickness. Each die stack on the wafer may then be singulated and packaged into an electronic device.

During the manufacturing process, the depth of the recessed portion may be configured to preserve the electrical integrity of the active side of the core semiconductor die and the mechanical integrity of the wafer, so that the wafer may be manipulated without breaking. For example, the depth of the recessed portion may be 50 μm or less. Also, the backgrinding or thinning of the resulting die stack may be configured to preserve both the electrical integrity of the active side of the secondary semiconductor die and the mechanical integrity of the wafer.

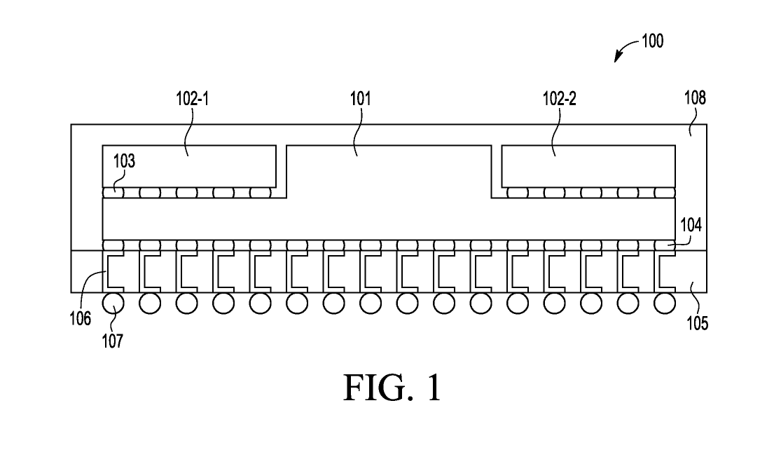

In some cases, a recessed semiconductor die stack as described herein may reduce signal delay between dies, and it may also minimize or reduce package thickness while preserving the mechanical or physical integrity of the dies. To further illustrate the foregoing, attention is now drawn to FIGS. 1-8.

FIG. 1 is a cross-sectional view of an example of a packaged electronic device including a recessed semiconductor die stack. As shown, device 100 includes first/core semiconductor die 101 and two secondary semiconductor dies, namely, second semiconductor die 102-1 and third semiconductor die 102-2. Second and third semiconductor dies 102-1 and 102-2 are disposed within recessed portions of first semiconductor die 101, and are coupled to first semiconductor die 101 via internal interconnects 103 (e.g., solder balls, bonding pads, terminals, etc.).

Semiconductor dies 101, 102-1, and 102-2 form a die stack that is encapsulated by encapsulant material 108 (e.g., an epoxy or the like). The die stack is coupled to substrate 105 via internal interconnects 104 (e.g., solder balls, bonding pads, terminals, etc.). Substrate 105 may have a variety of forms including a stamped lead frame, a ceramic substrate, a printed circuit board substrate, or the like. Also, substrate 105 may include conductive traces 106 that couple internal interconnects 104 to external interconnects 107 (e.g., ball grid array, pin-leads, terminals, etc.). In other embodiments, however, the die stack may be left as a bare die to be coupled to the substrate and not encapsulated.

Generally speaking, semiconductor dies 101, 102-1, and 102-2 may be any type of integrated circuit, semiconductor device, or other type of electrically active substrate. For example, in some implementations, core semiconductor die 101 may include a processor, and secondary semiconductor dies 102-1 and 102-2 may each include memory circuit(s), memory cells, or the like. Although not shown for sake of simplicity, traces and/or conductive vias within semiconductor dies 101, 102-1, and 102-2 may selectively interconnect their respective electrical circuits.

It should be noted that the embodiment of FIG. 1 shows each of two secondary semiconductor dies 102-1 and 102-2 symmetrically disposed in a symmetrically formed recessed portions of a single core die 101. In other embodiments, however, any number of dies and recessed portions may be used, and the resulting die stack does not need to be symmetrical—e.g., a single secondary day may be incorporated into a recessed portion of a core die in an off-center position. Additionally or alternatively, die 102-1 may be different from die 102-2, and may have different sizes, thickness, etc. Also, in certain embodiments, two or more secondary dies may be disposed within a single recessed portion of a core die (e.g., in a side-by-side configuration with respect to each other).

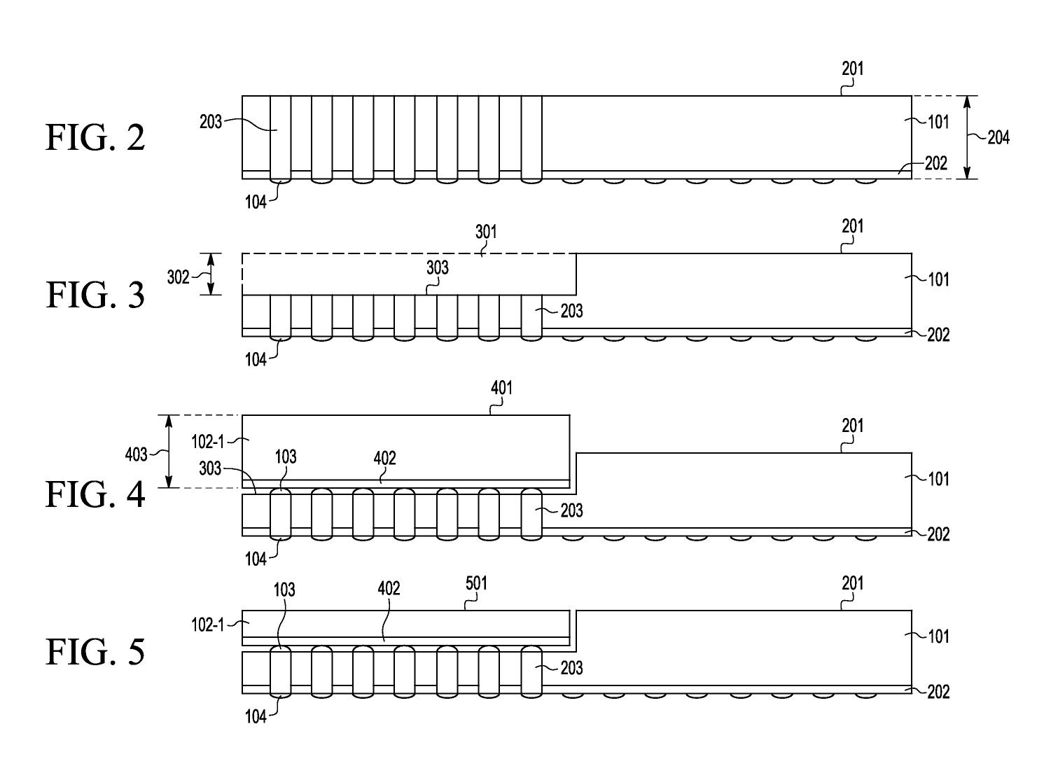

FIGS. 2-5 are diagrams illustrating examples of semiconductor processing operations that may be used to create a recessed semiconductor die stack. In FIG. 2, core semiconductor 101 of thickness 204 is shown, and it may be part of a non-singulated wafer or the like. Core die 101 includes active side/surface 202 and passive or back side/surface 201 located opposite active side 202. Active side 202 is the portion of core die 101 that includes electronic, mechanical, and/or electro-mechanical components fabricated thereon, and it is thinner than total core die 101's thickness 204.

Moreover, core die 101 includes a plurality of TSVs 203, as well as corresponding interconnects 104. Interconnects 104 are shown as connects to TSVs for simplicity; however, actual interconnects 104 may also be routed on the active surface to other TSVs in the main die. Each of TSVs 203 may be filled with an electrically conductive material such as copper, aluminum, or the like, and bonding pads are formed over the surface to facilitate subsequent electrical connections.

Moreover, core die 101 includes a plurality of THVs 203, as well as corresponding interconnects 104. Each of THVs 203 may be filled with an electrically conductive material such as copper, aluminum, solder, or the like.

FIG. 3 shows recess portion 301 removed from back side 201 of core die 101. For example, recess portion 301 may be created by selectively etching or grinding a portion of back side 201 of core die 101. Etching recess portion 301 may be performed, for example, using standard TSV creation techniques where a resist is patterned and a chemical etch is used to remove the recess portion 301. Alternatively, a grinding or laser ablation operation may be used to remove the recess portion 301. As such, recess portion 301 may have recess depth 302. The length of TSVs 203 in recess portion 301 is also reduced. In some cases, bonding pads (not shown) may be formed over recessed surface 303 for each of TSVs 203 to facilitate subsequent electrical connections within the resulting die stack.

FIG. 4 shows second semiconductor die 102-1 having second thickness 403 and disposed in recess portion 301 of core die 101. For example, die 102-1 may be coupled to die 101 by use of solder 103 and reflowed to solidify the electrical connections. Additionally or alternatively, underfill and/or adhesive may be used to fill one or more gaps between solder spheres. Similarly as core die 101, second die 102-1 also includes active side/surface 402 and passive or back side/surface 401 opposite active side 402. Active side 402 is nearest recessed surface 303. Moreover, pads or terminals on active surface 402 of second die 102-1 are coupled to TSVs 203 via internal interconnects 103. Again, this coupling may be achieved using standard die-to-die TSV connections such as solder, etc. and then reflowed. Also, underfilling may be used to fill the gaps between solder spheres.

In FIG. 5, a backgrinding, planarizing, or thinning process may be used to reduce thickness 403 of second semiconductor die 102-1, such that reduced back side 501 is aligned with original back side 201 of core die 101. In some cases, a backgrinding process or the like may also reduce thickness 204 such that both core die 101 and second die 102-1 have passive material removed from their respective back sides. For example, material from die 102-1 may be removed so that only the minimal silicon remains. In some cases, the final die 102-2's thickness may be approximately (i.e., ±1%, ±5%, or ±10%) 10 μm or more.

In some implementations, standard wafer backgrind process may be used to remove the excess material of die 102-1. Because this operation is performed on wafer level, multiple die may have material removed at the same time. In order to address potential grinding issues, in some cases it may be desirable to fill gaps between the multiple 102-1 dice with a filler material to present a level surface for the backgrind tool.

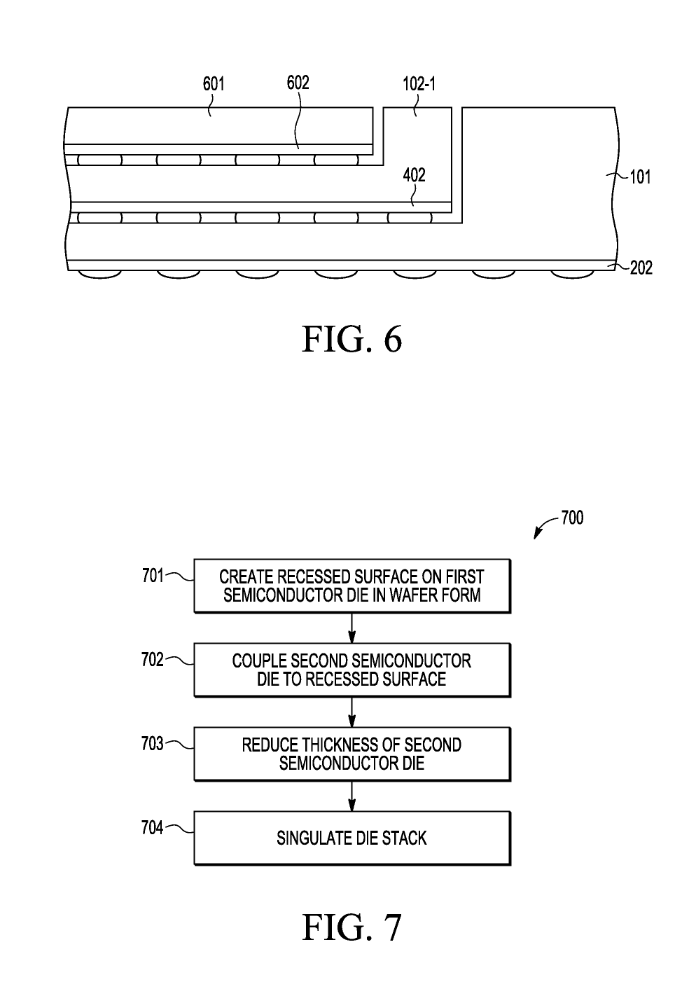

As noted above, recess depth 302 may be such that it preserves the electrical integrity of active side 202 of the core die 101, and the mechanical integrity of its host wafer. In some cases, thickness 204 of core die 101 may be approximately (i.e., ±1%, ±5%, or ±10%) 100 μm, and recess depth 302 may be approximately 50 μm. In other cases, recess depth 302 may be approximately 25 μm. Also, the backgrinding or thinning shown in FIG. 6 may be such that it preserves the electrical integrity of active side 402 of second die 102-1, and the mechanical integrity of the wafer. In some cases, the overall thickness of the resulting die stack may be maintained at approximately 100 μm. In other cases, the thickness of the resulting die stack may be approximately 50 μm.

In some embodiments, after the backgrinding operation of FIG. 6 is performed, each die stack on the wafer may be singulated. Then, each singulated die stack may be packaged to yield devices similar to that shown in FIG. 1, or with any other suitable configuration.

In some embodiments, more than two semiconductor dies may be stacked on top of each other. To illustrate this, FIG. 6 is a cross-sectional view of an example of a recessed semiconductor die stack having three semiconductor dies. As discussed above, core semiconductor die 101 has a recessed portion configured to receive second semiconductor die 102-1. In addition, second semiconductor die 102-1 includes its own TSVs (not shown), such that a recessed portion may be created on it to accommodate third semiconductor die 601.

Similarly as core die 101 and second die 102-1, third die 601 also includes active side/surface 602. Furthermore, active side 602 is nearest the recessed surface of second die 102-1; that is, each of dies 101, 102-1, and 601 in the resulting die stack is flipped over such that, when packaged, their respective active sides are facing the package's substrate 105. In some cases, it may be desirable that die 601 be mounted and back grinded to be level with die 102-1 before the entire assembly is mounted on die 101. For example, it may be desirable to mount die 102-1 on die 101 first, and then mount die 601 on die 102-1. The entire recessed semiconductor die stack may then be backgrinded at once, in one operation.

In some embodiments, a given die may be manufactured with less expensive (or different) technology another die in the same die stack. For example, a processor die (e.g., die 101-1) may be manufactured with a more advanced technology, such as 28 nm, while a memory die (e.g., die 102-1) may be manufactured with a less advanced technology, such as 90 nm. Such an embodiment may offer an advantage in decoupling the memory technology from the processor die, while still being able to integrate different technology nodes in the same package, and potentially save costs.

FIG. 7 is a flowchart of an example of a method for creating a recessed semiconductor die stack. Often, this is done in wafer format (before die singulation). At block 701, method 700 includes creating recessed surface 303 on first semiconductor die 101. Particularly, first semiconductor die 101 may have thickness 204, and recessed surface 303 may be at recess depth 302 that is smaller than thickness 204. At block 702, method 700 includes coupling second semiconductor die 102-1 to recessed surface 303. For example, second semiconductor die 102-1 may have thickness 403 that is greater than recess depth 302.

Then, at block 703, method 700 includes, after having coupled second semiconductor die 102-1 to recessed surface 303, reducing thickness 403 of second semiconductor die 102-1 by an amount equal to or greater than a difference between the thickness 403 and recess depth 302. Subsequent operations may include, for example, singulating each die stack and packaging the individual die stacks to produce an electronic device.

As discussed herein, in an illustrative, non-limiting embodiment, a semiconductor device may include a first semiconductor die including an active side and a back side opposite the active side, the back side including a non-recessed portion thicker than a recessed portion, the recessed portion including one or more through-die vias on a recessed surface; and a second semiconductor die located in the recessed portion of the first semiconductor die, the second semiconductor die including an active side facing the recessed surface of the first semiconductor die, the second semiconductor die coupled to the first semiconductor die through the one or more through-die vias. In some implementations, the first semiconductor die may include a processor and the second semiconductor die may include an application-specific die. For example, the application-specific die may be a memory.

The back side of the first semiconductor die may be in a plane with a back side of the second semiconductor die. Also, the recessed portion may have a depth of 50 μm or less.

Additionally or alternatively, the recessed portion may have a depth of 25 μm or less.

In some cases, the back side of the first semiconductor die may include another recessed portion, the other recessed portion including one or more other through-die vias on another recessed surface, the semiconductor device further comprising a third semiconductor die located in the other recessed portion of the first semiconductor die and coupled to the first semiconductor die through the one or more other through-die vias. The third semiconductor die may include an active side and a back side opposite the active side, the active side of the third semiconductor die facing the other recessed surface of the first semiconductor die, the back side of the third semiconductor die aligned with a back side of the second semiconductor die and the back side of the first semiconductor die.

The second semiconductor die may include a back side opposite the second semiconductor die's active side, where the back side of the second semiconductor die includes another recessed portion, and where the other recessed portion of the second semiconductor die includes one or more other through-die vias on another recessed surface. The semiconductor device may also include a third semiconductor die located in the other recessed portion of the second semiconductor die and coupled to the second semiconductor die through the one or more other through-die vias. In some cases, the third semiconductor die may include an active side and a back side opposite the active side, the active side of the third semiconductor die facing the other recessed surface of the second semiconductor die, the back side of the third semiconductor die aligned with the back sides of the first and second semiconductor dies.

In another illustrative, non-limiting embodiment, a method includes creating a recessed surface on a first semiconductor die, the first semiconductor die having a first thickness and the recessed surface having a recess depth smaller than the first thickness; coupling a second semiconductor die to the recessed surface, the second semiconductor die having a second thickness greater than the recess depth; and reducing the thickness of the second semiconductor die by an amount equal to or greater than a difference between the second thickness and the recess depth.

In some cases, creating the recessed surface may include etching a portion of the first semiconductor die. For example, the recess depth may be 50 μm or less. Additionally or alternatively, the recess depth may be 25 μm or less. Also, recessed surface may include through-die vias filled with conductive material, the method further including, prior to coupling the second semiconductor die to the recessed surface, forming bonding pads on the recessed surface corresponding to the through-die vias.

In some implementations, coupling the second semiconductor die to the recessed surface may include coupling pads on the semiconductor die to the formed bonding pads on the recessed surface. For instance, the first semiconductor die may include a processor and the second semiconductor die may include a memory. Additionally or alternatively, reducing the thickness of the second semiconductor die may include planarizing the backside of the first semiconductor die with the backside of the second semiconductor die to the same plane.

The first semiconductor die may be part of a non-singulated wafer, the method further comprising performing a singulation operation after the planarizing. The method may also include creating a recessed surface on the second semiconductor die; and coupling a third semiconductor die to the recessed surface of the second semiconductor die.

In many implementations, the systems and methods disclosed herein may be incorporated into a wide range of electronic devices including, for example, computer systems or Information Technology (IT) products such as servers, desktops, laptops, memories, switches, routers, etc.; telecommunications hardware; consumer devices or appliances such as mobile phones, tablets, television sets, cameras, sound systems, etc.; scientific instrumentation; industrial robotics; medical or laboratory electronics such as imaging, diagnostic, or therapeutic equipment, etc.; transportation vehicles such as automobiles, buses, trucks, trains, watercraft, aircraft, etc.; military equipment, etc. More generally, these systems and methods may be incorporated into any device or system having one or more electronic parts or components.

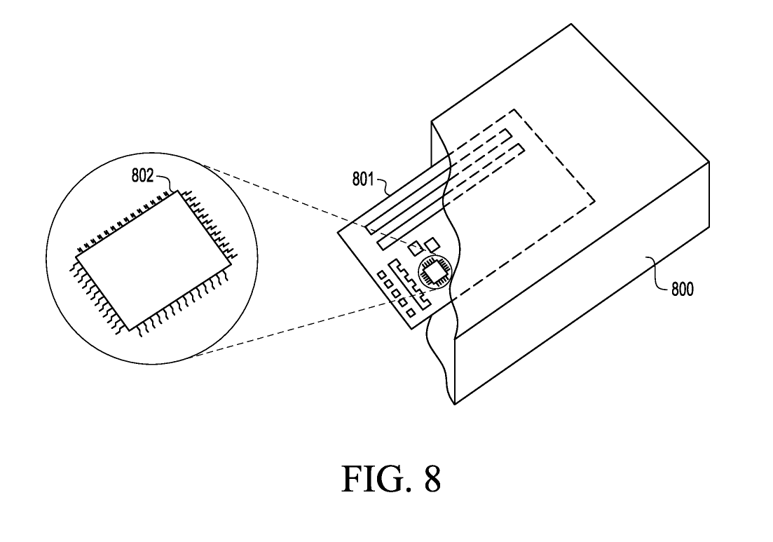

Turning to FIG. 8, a block diagram of electronic device 800 is depicted. In some embodiments, electronic device 800 may be any of the aforementioned electronic devices, or any other electronic device. As illustrated, electronic device 800 includes one or more Printed Circuit Boards (PCBs) 801, and at least one of PCBs 801 includes one or more microelectronic device packages(s) 802. In some implementations, device package(s) 802 may include one or more recessed semiconductor die stacks discussed above.

Examples of device package(s) 802 may include, for instance, a System-On-Chip (SoC), an Application Specific Integrated Circuit (ASIC), a Digital Signal Processor (DSP), a Field-Programmable Gate Array (FPGA), a processor, a microprocessor, a controller, a microcontroller (MCU), a Graphics Processing Unit (GPU), or the like. Additionally or alternatively, device package(s) 802 may include a memory circuit or device such as, for example, a Random Access Memory (RAM), a Static RAM (SRAM), a Magnetoresistive RAM (MRAM), a Nonvolatile RAM (NVRAM, such as “FLASH” memory, etc.), and/or a Dynamic RAM (DRAM) such as Synchronous DRAM (SDRAM), a Double Data Rate RAM, an Erasable Programmable ROM (EPROM), an Electrically Erasable Programmable ROM (EEPROM), etc. Additionally or alternatively, device package(s) 802 may include one or more mixed-signal or analog circuits, such as, for example, Analog-to-Digital Converter (ADCs), Digital-to-Analog Converter (DACs), Phased Locked Loop (PLLs), oscillators, filters, amplifiers, etc. Additionally or alternatively, device package(s) 802 may include one or more Micro-ElectroMechanical Systems (MEMS), Nano-ElectroMechanical Systems (NEMS), or the like.

Generally speaking, device package(s) 802 may be configured to be mounted onto PCB 801 using any suitable packaging technology such as, for example, Ball Grid Array (BGA) packaging or the like. In some applications, PCB 801 may be mechanically mounted within or fastened onto electronic device 800. It should be noted that, in certain implementations, PCB 801 may take a variety of forms and/or may include a plurality of other elements or components in addition to device package(s) 802. It should also be noted that, in some embodiments, PCB 801 may not be used and/or device package(s) 802 may assume any other suitable form(s).

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. A semiconductor device, comprising:
a first semiconductor die including an active side and a back side opposite the active side, the back side including a non-recessed portion thicker than a recessed portion, the recessed portion including one or more through-die vias on a recessed surface; and
a second semiconductor die located in the recessed portion of the first semiconductor die, the second semiconductor die including an active side facing the recessed surface of the first semiconductor die, the second semiconductor die coupled to the first semiconductor die through the one or more through-die vias.

2. The semiconductor device of claim 1, wherein the first semiconductor die includes a processor and wherein the second semiconductor die includes an application-specific die.

3. The semiconductor device of claim 3, wherein the application-specific die is a memory.

4. The semiconductor device of claim 1, wherein the back side of the first semiconductor die is in a plane with a back side of the second semiconductor die.

5. The semiconductor device of claim 1, wherein the recessed portion has a depth of 50 μm or less.

6. The semiconductor device of claim 6, wherein the recessed portion has a depth of 25 μm or less.

7. The semiconductor device of claim 1, wherein the back side of the first semiconductor die includes another recessed portion, the other recessed portion including one or more other through-die vias on another recessed surface, the semiconductor device further comprising a third semiconductor die located in the other recessed portion of the first semiconductor die and coupled to the first semiconductor die through the one or more other through-die vias.

8. The semiconductor device of claim 8, wherein the third semiconductor die includes an active side and a back side opposite the active side, the active side of the third semiconductor die facing the other recessed surface of the first semiconductor die, the back side of the third semiconductor die aligned with a back side of the second semiconductor die and the back side of the first semiconductor die.

9. The semiconductor device of claim 1, wherein the second semiconductor die includes a back side opposite the second semiconductor die's active side, wherein the back side of the second semiconductor die includes another recessed portion, and wherein the other recessed portion of the second semiconductor die includes one or more other through-die vias on another recessed surface, the semiconductor device further comprising a third semiconductor die located in the other recessed portion of the second semiconductor die and coupled to the second semiconductor die through the one or more other through-die vias.

10. The semiconductor device of claim 10, wherein the third semiconductor die includes an active side and a back side opposite the active side, the active side of the third semiconductor die facing the other recessed surface of the second semiconductor die, the back side of the third semiconductor die aligned with the back sides of the first and second semiconductor dies.

11. A method, comprising:
creating a recessed surface on a first semiconductor die, the first semiconductor die having a first thickness and the recessed surface having a recess depth smaller than the first thickness;
coupling a second semiconductor die to the recessed surface, the second semiconductor die having a second thickness greater than the recess depth; and
reducing the thickness of the second semiconductor die by an amount equal to or greater than a difference between the second thickness and the recess depth.

12. The method of claim 11, wherein creating the recessed surface includes etching a portion of the first semiconductor die.

13. The method of claim 11, wherein the recess depth is 50 μm or less.

14. The method of claim 13, wherein the recess depth is 25 μm or less.

15. The method of claim 11, wherein the recessed surface includes through-die vias filled with conductive material, the method further comprising, prior to coupling the second semiconductor die to the recessed surface, forming bonding pads on the recessed surface corresponding to the through-die vias.

16. The method of claim 15, wherein coupling the second semiconductor die to the recessed surface includes coupling pads on the semiconductor die to the formed bonding pads on the recessed surface.

17. The method of claim 11, wherein the first semiconductor die includes a processor and wherein the second semiconductor die includes a memory.

18. The method of claim 11, wherein reducing the thickness of the second semiconductor die includes planarizing the backside of the first semiconductor die with the backside of the second semiconductor die to the same plane.

19. The method of claim 18, wherein the first semiconductor die is part of a non-singulated wafer, the method further comprising performing a singulation operation after the planarizing.

20. The method of claim 11, further comprising:
creating a recessed surface on the second semiconductor die; and
coupling a third semiconductor die to the recessed surface of the second semiconductor die.
